(19) United States
(12) Patent Application Publication
(10) Pub. No.: US 2026/0143814 A1
(43) Pub. Date: May 21, 2026

(54) SEMICONDUCTOR DEVICE AND DISPLAY DEVICE

(71) Applicant: Japan Display Inc., Tokyo (JP)

(72) Inventors: Hajime WATAKABE, Tokyo (JP); Masashi TSUBUKU, Tokyo (JP); Toshinari SASAKI, Tokyo (JP); Takaya TAMARU, Tokyo (JP); Marina MOCHIZUKI, Tokyo (JP); Masahiro WATABE, Tokyo (JP)

(73) Assignee: Japan Display Inc., Tokyo (JP)

(21) Appl. No.: 19/359,882

(22) Filed: Oct. 16, 2025

(30) Foreign Application Priority Data
Nov. 21, 2024 (JP) 2024-203018
Oct. 7, 2025 (JP) 2025-169047

(51) Int. Cl. H10D 86/40; H10D 86/01; H10D 86/60; H10K 59/12; H10K 59/123

(52) U.S. Cl. CPC H10D 86/423; H10D 86/0221; H10D 86/60; H10K 59/1201; H10K 59/123

(57) ABSTRACT

A semiconductor device includes a first transistor including a first oxide semiconductor layer on a first insulating layer, a second insulating layer on the first oxide semiconductor layer and a first gate electrode on the second insulating layer, and a second transistor including a second oxide semiconductor layer covering an opening arranged in the first insulating layer, the second insulating layer being located on the second oxide semiconductor layer and a second gate electrode being located on the second insulating layer. The second transistor is configured such that a portion of the second oxide semiconductor layer along a sidewall of the opening functions as a channel.

### CROSS-REFERENCE TO RELATED APPLICATIONS

This application claims the benefit of priority to Japanese Patent Application No. 2024-203018, filed on Nov. 21, 2024, and Japanese Patent Application No. 2025-169047, filed on Oct. 7, 2025, the entire contents of each are incorporated herein by reference.

### FIELD

One embodiment of the present invention relates to a semiconductor device using an oxide semiconductor and a display device incorporating the same.

### BACKGROUND

Recently, semiconductor devices using an oxide semiconductor have been developed in place of silicon semiconductors using amorphous silicon, low-temperature polysilicon, and single-crystal silicon, and the like, (e.g., Japanese laid-open patent publication No. 2021-141338, Japanese laid-open patent publication No. 2014-099601, Japanese laid-open patent publication No. 2021-153196, Japanese laid-open patent publication No. 2018-006730, Japanese laid-open patent publication No. 2016-184771, and Japanese laid-open patent publication No. 2021-108405). For example, a transistor that utilizes an oxide semiconductor layer containing the oxide semiconductor as a channel can be manufactured in a simple structure and low temperature processing, similar to a transistor that includes an amorphous silicon layer. A transistor including the oxide semiconductor layer is known to have higher field-effect mobility than the transistor containing the amorphous silicon layer.

### SUMMARY

A semiconductor device according to an embodiment of the present invention includes a first transistor including a first oxide semiconductor layer on a first insulating layer, a second insulating layer on the first oxide semiconductor layer and a first gate electrode on the second insulating layer, and a second transistor including a second oxide semiconductor layer covering an opening arranged in the first insulating layer, the second insulating layer being located on the second oxide semiconductor layer and a second gate electrode being located on the second insulating layer. The second transistor is configured such that a portion of the second oxide semiconductor layer along a sidewall of the opening functions as a channel.

A semiconductor device according to an embodiment of the present invention includes a first transistor including a first gate electrode on an insulating surface, a first insulating layer on the first gate electrode and a first oxide semiconductor layer on the first insulating layer; and a second transistor including a second oxide semiconductor layer covering an opening arranged in the first insulating layer, a second insulating layer being located on the second oxide semiconductor layer and a second gate electrode being located on the second insulating layer. The second transistor is configured such that a portion of the second oxide semiconductor layer along a sidewall of the opening functions as a channel.

### BRIEF DESCRIPTION OF THE DRAWINGS

FIG. 1 is a schematic plan view showing a configuration of a display device including a semiconductor device according to an embodiment of the present invention.

FIG. 2 is a schematic circuit diagram showing an equivalent circuit of a pixel including a semiconductor device according to an embodiment of the present invention.

FIG. 3 is a schematic cross-sectional view showing a configuration of a semiconductor device according to an embodiment of the present invention.

FIG. 4 is a schematic plan view showing a configuration of a first transistor of a semiconductor device according to an embodiment of the present invention.

FIG. 5 is a schematic plan view showing a configuration of a second transistor of a semiconductor device according to an embodiment of the present invention.

FIG. 6 is a flowchart for explaining a method for manufacturing a pixel including a semiconductor device according to an embodiment of the present invention.

FIG. 7 is a schematic cross-sectional view showing a method for manufacturing a pixel including a semiconductor device according to an embodiment of the present invention.

FIG. 8 is a schematic cross-sectional view showing a method for manufacturing a pixel including a semiconductor device according to an embodiment of the present invention.

FIG. 9 is a schematic cross-sectional view showing a method for manufacturing a pixel including a semiconductor device according to an embodiment of the present invention.

FIG. 10 is a schematic cross-sectional view showing a method for manufacturing a pixel including a semiconductor device according to an embodiment of the present invention.

FIG. 11 is a schematic cross-sectional view showing a method for manufacturing a pixel including a semiconductor device according to an embodiment of the present invention.

FIG. 12 is a schematic cross-sectional view showing a method for manufacturing a pixel including a semiconductor device according to an embodiment of the present invention.

FIG. 13 is a schematic cross-sectional view showing a method for manufacturing a pixel including a semiconductor device according to an embodiment of the present invention.

FIG. 14 is a schematic cross-sectional view showing a method for manufacturing a pixel including a semiconductor device according to an embodiment of the present invention.

FIG. 15 is a schematic cross-sectional view showing a method for manufacturing a pixel including a semiconductor device according to an embodiment of the present invention.

FIG. 16 is a schematic cross-sectional view showing a method for manufacturing a pixel including a semiconductor device according to an embodiment of the present invention.

FIG. 17 is a schematic cross-sectional view showing a method for manufacturing a pixel including a semiconductor device according to an embodiment of the present invention.

FIG. 18 is a schematic cross-sectional view showing a method for manufacturing a pixel including a semiconductor device according to an embodiment of the present invention.

FIG. 19 is a schematic cross-sectional view showing a method for manufacturing a pixel including a semiconductor device according to an embodiment of the present invention.

FIG. 20 is a schematic cross-sectional view showing a method for manufacturing a pixel including a semiconductor device according to an embodiment of the present invention.

FIG. 21 is a flowchart for explaining a method for manufacturing a pixel including a semiconductor device according to an embodiment of the present invention.

FIG. 22 is a schematic cross-sectional view showing a method for manufacturing a pixel including a semiconductor device according to an embodiment of the present invention.

FIG. 23 is a schematic cross-sectional view showing a method for manufacturing a pixel including a semiconductor device according to an embodiment of the present invention.

FIG. 24 is a schematic cross-sectional view showing a method for manufacturing a pixel including a semiconductor device according to an embodiment of the present invention.

FIG. 25 is a schematic cross-sectional view showing a method for manufacturing a pixel including a semiconductor device according to an embodiment of the present invention.

FIG. 26 is a schematic cross-sectional view showing a method for manufacturing a pixel including a semiconductor device according to an embodiment of the present invention.

FIG. 27 is a schematic cross-sectional view showing a method for manufacturing a pixel including a semiconductor device according to an embodiment of the present invention.

### DESCRIPTION OF EMBODIMENTS

With the miniaturization of semiconductor devices, there is demand for higher integration of transistors that includes an oxide semiconductor layer. In particular, there is strong demand for high integration of transistors used in a pixel of a display device. In addition, for example, a plurality of transistors is used as a pixel of an organic EL display device, and the required specifications for each transistor may differ. Therefore, in a semiconductor device using an oxide semiconductor, there is demand for a technique for adjusting device characteristics depending on the required specifications.

An object of one embodiment of the present invention is to achieve high integration of a semiconductor device using an oxide semiconductor.

In addition, an object of one embodiment of the present invention is to make the characteristics of individual transistors forming a semiconductor device using an oxide semiconductor different.

Hereinafter, embodiments of the present invention will be described with reference to the drawings. The following disclosure is merely an example. A configuration that can be easily conceived by a person skilled in the art by appropriately changing the configuration of the embodiment while keeping the gist of the invention is naturally included in the scope of the present invention. For clarity of explanation, the drawings may be schematically represented with respect to widths, thicknesses, shapes, and the like of components in comparison with actual embodiments. However, the illustrated shapes are merely examples, and do not limit the interpretation of the present invention. In the present specification, the claims, and the drawings (hereinafter, referred to as “the present specification and the like”), the same components as those described above with respect to the above-described drawings are denoted by the same reference signs, and the detailed description thereof may be omitted as appropriate.

In the present specification and the like, a direction from a substrate toward an oxide semiconductor layer is referred to as “upper” or “above”. Conversely, a direction from the oxide semiconductor layer toward the substrate is referred to as “lower” or “below”. As described above, for convenience of explanation, the terms “above” and “below” are used, but the upper and lower relationship between the substrate and the oxide semiconductor layer may be opposite to the drawings. In addition, the expression “an oxide semiconductor layer on a substrate” merely describes the upper and lower relationship between the substrate and the oxide semiconductor layer, and other members may be arranged between the substrate and the oxide semiconductor layer. Above or below means a stacking order in a structure in which a plurality of layers is stacked, and when expressed as “a pixel electrode above a semiconductor device,” it may be a positional relationship in which the semiconductor device and the pixel electrode do not overlap in a plan view. On the other hand, when expressed as a pixel electrode vertically above a semiconductor device, it means a positional relationship in which the semiconductor device and the pixel electrode overlap in a plan view. In addition, the plan view means a view perpendicular to a surface of the substrate.

In the present specification and the like, a plurality of elements formed by processing a certain film, such as etching, may be described as elements having different functions or roles. These elements are composed of the same layer structure and the same material, and are described as elements composed of the same layer. That is, in the present specification and the like, when it is described that “A and B are the same layer”, it means that the element A and the element B are both elements formed by processing a single layer.

In this specification and the like, the expressions “α includes A, B, or C”, “α includes any of A, B, and C”, “α includes one selected from a group consisting of A, B, and C” do not exclude the case where α includes a plurality of combinations of A to C unless otherwise specified. Further, these expressions do not exclude the case where α includes other components.

In the present specification and the like, the term “semiconductor device” refers to any device that can function by utilizing semiconductor properties. A transistor and a semiconductor circuit are included in one form of the semiconductor device. For example, the semiconductor device of the embodiments described below can be used in an integrated circuit (IC) such as a display device or a micro-processing unit (MPU), or in a memory circuit.

In the present specification and the like, the term “display device” refers to a structure that displays an image using an electro-optic layer. For example, the term “display device” may refer to a display panel that includes an electro-optic layer, or may refer to a structure with other optical members (e.g., polarized member, backlight, touch panel, etc.) attached to a display cell. The “electro-optic layer” may include a liquid crystal layer, an electroluminescent (EL) layer, an electrochromic (EC) layer, and an electrophoretic layer, as long as there is no technical contradiction. Therefore, although the embodiment to be described later is described by exemplifying an organic EL display device, which includes an organic EL layer, as a display device, the structure in the present embodiment can be applied to a display device that includes the other electro-optic layers described above.

In the present specification and the like, the terms “film” and “layer” can optionally be interchanged.

The functions of a source and a drain of the transistor may be interchanged depending on the voltage supplied to each of them. Therefore, in the present specification and the like, the term “source” and the term “drain” may be interchanged.

In addition, the following embodiments can be combined with each other as long as there is no technical contradiction.

### First Embodiment

### Configuration of Display Device

Hereinafter, a display device 10 according to an embodiment of the present invention will be described. In the present embodiment, an organic EL display device is exemplified as the display device 10. The organic EL display device is a display device that includes, in each pixel, an organic EL element as a light-emitting element, and a semiconductor device for driving the light-emitting element.

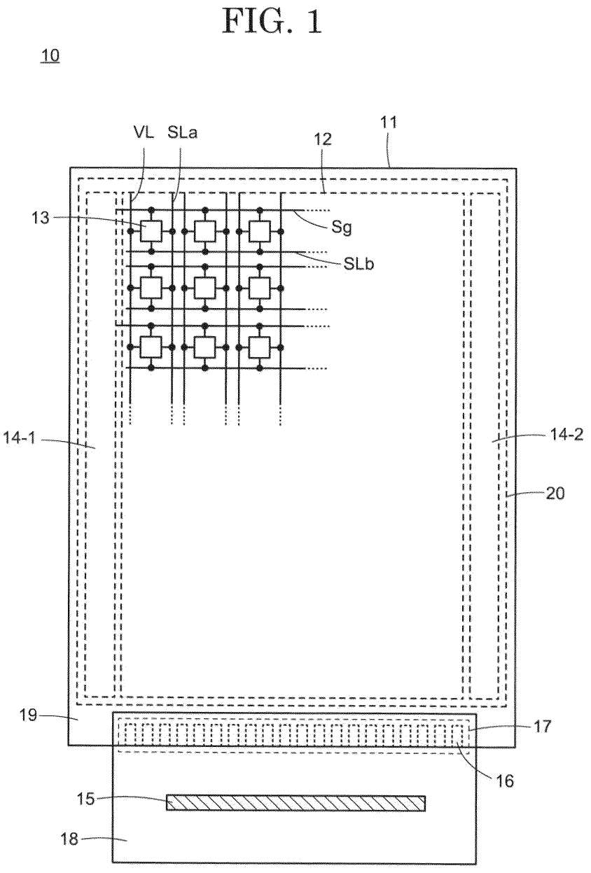

FIG. 1 is a schematic plan view showing a configuration of the display device 10 including a semiconductor device according to an embodiment of the present invention. As shown in FIG. 1, the display device 10 includes a display portion 12 and a peripheral portion 19 provided on a substrate 11. The display portion 12 includes a plurality of pixels 13 arranged in a matrix. Each of the plurality of pixels 13 includes a semiconductor device and a light-emitting element formed by a plurality of transistors described later. A touch sensor 20 is arranged on the display portion 12.

The peripheral portion 19 is provided to surround the display portion 12. The peripheral portion 19 refers to a portion of the substrate 11 from the display portion 12 to the end portion of the substrate 11. In other words, the peripheral portion 19 refers to a portion other than the portion where the display portion 12 is provided on the substrate 11 (specifically, the outer portion of the display portion 12). The peripheral portion 19 includes gate drive circuits 14-1 and 14-2 and a terminal portion 17 including a plurality of terminals 16. The gate drive circuits 14-1 and 14-2 are provided to sandwich the display portion 12. The terminal portion 17 is connected to a flexible printed circuit 18 on which a driver IC 15 is mounted. A plurality of wirings (not shown) included in the flexible printed circuit 18 is connected to the driver IC 15 and the terminal portion 17. In the example shown in FIG. 1, a source driver circuit is incorporated in the driver IC 15. However, the present invention is not limited to this example, and the source driver circuit may be formed on the substrate 11 using a transistor.

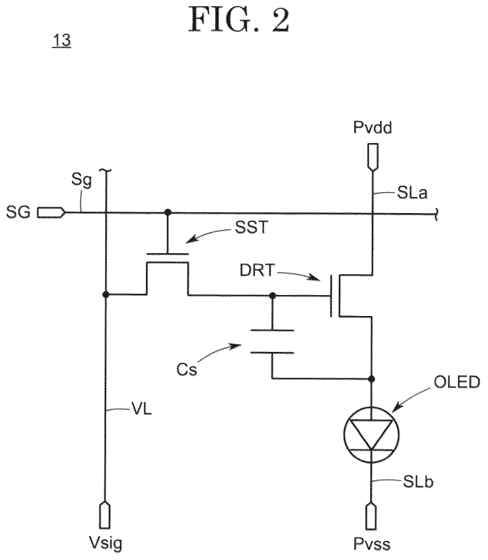

The driver IC 15 is connected to the gate drive circuits 14-1 and 14-2 and a plurality of video signal lines VL. The gate drive circuit 14-1 or gate drive circuit 14-2 is connected to the pixel 13 via a selection control line Sg. Among a plurality of selection control lines Sg, for example, the selection control line Sg in an odd-numbered row is connected to the gate drive circuit 14-1, and the selection control line Sg in an even-numbered row is connected to the gate drive circuit 14-2. The video signal line VL is connected to the pixel 13. A control signal SG (see FIG. 2) for selecting each pixel 13 is supplied from the driver IC 15 via the gate drive circuits 14-1 and 14-2 and the selection control line Sg to the display portion 12. In addition, a video signal Vsig (see FIG. 2) is supplied from the driver IC 15 via the video signal line VL to the display portion 12. With these signals, the plurality of transistors included in the pixel 13 can be driven, and an image can be displayed on the display portion 12 according to the video signal Vsig. A high voltage power line SLa and a low voltage power line SLb connected to the pixel 13 are connected to different terminals 16, respectively.

A glass substrate, a quartz substrate, a ceramic substrate, and a plastic substrate or resin substrate having flexibility can be used as the substrate 11. In the case where the plastic substrate or resin substrate having flexibility is used as the substrate 11, the substrate 11 can be bent between the display portion 12 and the terminal portion 17. This makes it possible to reduce the area of the bezel part of the display device 10.

### Configuration of Pixel Circuit

FIG. 2 is a schematic circuit diagram showing a circuit configuration of the pixel 13 including a semiconductor device according to an embodiment. The high voltage power line SLa, the low voltage power line SLb, the selection control line Sg, and the video signal line VL are connected to each pixel 13 forming the display device 10. The high voltage power line SLa is connected to a high potential power line Pvdd. The low voltage power line SLb is connected to a low potential power line Pvss. The selection control line Sg is connected to the gate drive circuits 14-1 and 14-2. The video signal line VL is connected to the driver IC 15 for supplying the video signal Vsig.

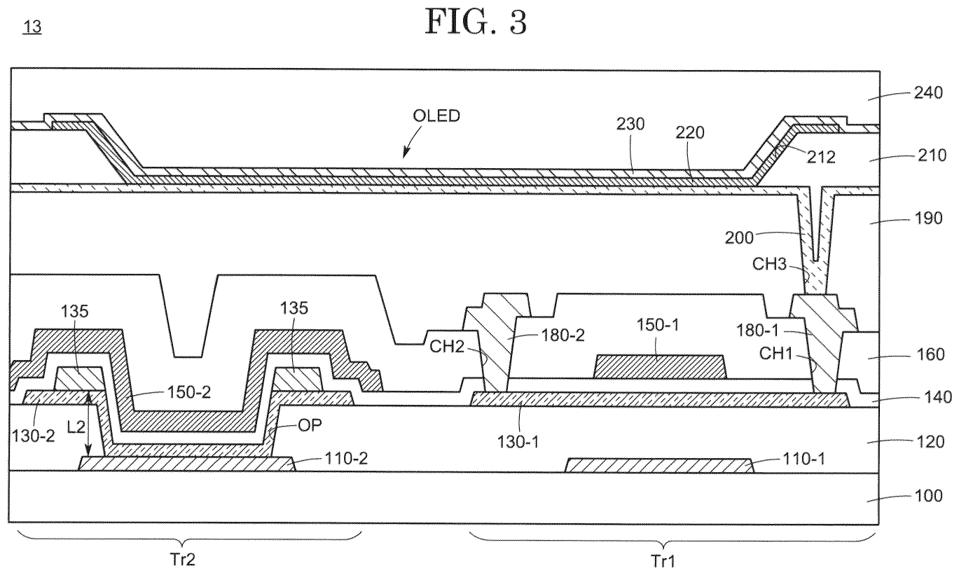

The pixel 13 includes at least a drive transistor DRT, a select transistor SST, and a light-emitting element OLED. The high potential power line Pvdd is connected to an anode of the light-emitting element OLED via the drive transistor DRT. The low potential power line Pvss is connected to a cathode of the light-emitting element OLED. In the present embodiment, the anode of the light-emitting element OLED is connected to a pixel electrode 200 (see FIG. 3) and the cathode is connected to a common electrode 230 (see FIG. 3).

The drive transistor DRT is connected in series with the light-emitting element OLED between the high voltage power line SLa and the low voltage power line SLb. The drive transistor DRT functions as a current control element that controls a current value flowing through the light-emitting element OLED according to a gate-source voltage. The select transistor SST functions as a switching element that selects conduction or non-conduction between two nodes, and applies a voltage corresponding to the luminance of the light-emitting element OLED to a gate of the drive transistor DRT. A storage capacitor Cs is provided between the gate-source of the drive transistor DRT. The storage capacitor Cs holds the gate-source voltage of the drive transistor DRT.

The select transistor SST includes a gate connected to the selection control line Sg, one of the source or the drain connected to the video signal line VL, and the other of the source or the drain connected to the gate of the drive transistor DRT and the storage capacitor Cs. The drive transistor DRT includes a drain connected to the high voltage power line SLa and a source connected to the storage capacitor Cs and the anode of the light-emitting element OLED. The cathode of the light-emitting element OLED is connected to the low voltage power line SLb. The drive transistor DRT outputs a driving current corresponding to the video signal Vsig to the light-emitting element OLED.

Although not shown, the pixel 13 may further include other transistors such as a correct transistor that corrects the threshold value of the drive transistor DRT and a reset transistor that resets the voltage held in the storage capacitor Cs.

In the present embodiment, an oxide semiconductor is used as the semiconductor used for the select transistor SST and the drive transistor DRT. The transistor using the oxide semiconductor has a low off-leakage current and can be driven at a low frequency, so that the advantage is low power consumption. Therefore, by configuring the pixel using the oxide semiconductor, the power consumption of the display device 10 can be reduced. Further, the transistor using the oxide semiconductor also has the advantage that no kink effect is observed and the saturation characteristics are good compared with those of the transistor using so-called low-temperature polysilicon.

### Structure of Pixel

FIG. 3 is a schematic cross-sectional view showing a configuration of a semiconductor device according to an embodiment of the present invention. The semiconductor device shown in FIG. 3 is a semiconductor circuit including at least a transistor Tr1 and a transistor Tr2. FIG. 3 shows an example in which the pixel 13 shown in FIG. 1 is provided with the semiconductor circuit including the transistor Tr1 and the transistor Tr2, but the pixel 13 may include more transistors.

First, a structure of the transistor Tr1 will be described. The transistor Tr1 of the present embodiment includes a conductive layer 110-1, an insulating layer 120, an oxide semiconductor layer 130-1, an insulating layer 140, a conductive layer 150-1, an insulating layer 160, a conductive layer 180-1, and a conductive layer 180-2 provided on a substrate 100 having an insulating surface.

For example, the substrate 100 is a substrate in which one or more insulating layers composed of an insulating oxide such as silicon oxide (SiOₓ) or silicon oxynitride (SiOₓN_{y}) or an insulating nitride such as silicon nitride (SiNₓ) or silicon nitride oxide (SiNₓO_{y}) are formed on a glass substrate. In this case, the silicon nitride oxide (SiNₓO_{y}) is a silicon oxide containing a smaller proportion (x>y) of oxygen than nitrogen. In addition, silicon oxynitride (SiOₓN_{y}) is a silicon nitride containing a smaller proportion (x>y) of nitrogen (N) than oxygen (O).

In the present embodiment, the substrate 100 having an insulating surface is formed by stacking a silicon nitride layer and a silicon oxide layer on a glass substrate in this order from the bottom. The silicon nitride layer serves as a protective layer that prevents the intrusion of contaminants (e.g., alkaline substances) from the glass substrate. However, the present invention is not limited to this example, and a quartz substrate, a ceramic substrate, a plastic substrate, or a resin substrate may be used instead of the glass substrate. In addition, the silicon oxide layer, the silicon nitride layer, and the silicon oxynitride layer or the silicon nitride oxide layer may be stacked in any order.

The conductive layer 110-1 is provided on the substrate 100. The conductive layer 110-1 functions as a lower-layer side gate electrode in the transistor Tr1. Aluminum (Al), copper (Cu), titanium (Ti), molybdenum (Mo), tantalum (Ta) or tungsten (W), an alloy thereof, or the like can be used as a material forming the conductive layer 110-1. In the present embodiment, a molybdenum-tungsten alloy is used as the material forming the conductive layer 110-1. The conductive layer 110-1 also functions as a light-shielding layer that reduces the light reaching the oxide semiconductor layer 130-1 from the lower-layer side.

The insulating layer 120 s provided on the conductive layer 110-1. The insulating layer 120 functions as a lower-layer side gate insulating layer in the transistor Tr1. One or more layers selected from a silicon oxide layer, a silicon nitride layer, a silicon oxynitride layer, or a silicon nitride oxide layer can be used as the insulating layer 120. In the present embodiment, an insulating layer in which a silicon nitride layer and a silicon oxide layer are stacked in this order from the bottom is used as the insulating layer 120. As will be described later, since the oxide semiconductor layers 130-1 and 130-2 are provided on the insulating layer 120, a surface of the insulating layer 120 in contact with the oxide semiconductor layers 130-1 and 130-2 is preferably a silicon oxide layer.

The thickness of the insulating layer 120 is not particularly limited. In the present embodiment, the thickness of the insulating layer 120 is set to 100 nm or more and 1000 nm or less (preferably 200 nm or more and 900 nm or less, more preferably 300 nm or more and 800 nm or less). In the present embodiment, a silicon oxide layer having a thickness of 300 nm is used as the insulating layer 120.

The oxide semiconductor layer 130-1 is provided on the insulating layer 120. The oxide semiconductor layer 130-1 functions as an active layer in the transistor Tr1. An oxide semiconductor having an amorphous structure or an oxide semiconductor having a polycrystal structure may be used as a material forming the oxide semiconductor layer 130-1. The thickness of the oxide semiconductor layer 130-1 can be 10 nm or more and 100 nm or less (preferably, 15 nm or more and 70 nm or less, more preferably, 15 nm or more and 40 nm or less).

The oxide semiconductor layer 130-1 can be formed using a sputtering method. A composition of the oxide semiconductor layer 130-1 formed using the sputtering method depends on a composition of a sputtering target.

A composition of a metal element forming the oxide semiconductor layer 130-1 can be specified based on a composition of a metal element forming the sputtering target. In addition, the composition of the metal elements forming the oxide semiconductor layer 130-1 can also be specified by using an X-ray diffraction (XRD) method. Specifically, the composition of the metal element forming the oxide semiconductor layer 130-1 can be specified based on a crystal structure and a lattice constant of the oxide semiconductor layer 130-1 obtained using the XRD method. In addition, the composition of the metal element forming the oxide semiconductor layer 130-1 can also be specified by using fluorescent X-ray analysis or electron probe micro analyzer (EPMA) analysis.

The insulating layer 140 is provided on the oxide semiconductor layer 130-1. The insulating layer 140 functions as an upper-layer side gate insulating layer in the transistor Tr1. One or more layers selected from a silicon oxide layer, a silicon nitride layer, a silicon oxynitride layer, or a silicon nitride oxide layer can be used as the insulating layer 140. In the present embodiment, a silicon oxide layer is used as the insulating layer 140. The insulating layer 140 functions as a gate insulating layer in both the transistor Tr1 and the transistor Tr2 described later. Therefore, a silicon-oxide layer is preferably used as the insulating layer 140. The insulating layer 140 preferably has few defects and a composition close to the stoichiometric ratio. Specifically, it is preferable that no defects are observed in the insulating layer 140 when evaluated by an electron spin resonance (ESR) method. The thickness of the insulating layer 140 is not particularly limited. In the present embodiment, the thickness of the insulating layer 140 is set to 50 nm or more and 300 nm or less (preferably 60 nm or more and 200 nm or less, more preferably 70 nm or more and 150 nm or less).

The conductive layer 150-1 is provided on the insulating layer 140. The conductive layer 150-1 functions as the upper-layer side gate electrode in the transistor Tr1. Aluminum (Al), copper (Cu), titanium (Ti), molybdenum (Mo), tantalum (Ta) or tungsten (W), an alloy thereof, or the like can be used as the material forming the conductive layer 150-1. In the present embodiment, a molybdenum-tungsten alloy is used as a material forming the conductive layer 110-1. The conductive layer 150-1 also functions as a light-shielding layer that reduces the light reaching the oxide semiconductor layer 130-1 from the upper-layer side.

The insulating layer 160 is provided on the conductive layer 150-1. The insulating layer 160 functions as an interlayer insulating layer in the transistor Tr1. One or more layers selected from a silicon oxide layer, a silicon nitride layer, a silicon oxynitride layer, or a silicon nitride oxide layer can be used as the insulating layer 160. In the present embodiment, a stacked structure including a silicon oxide layer and a silicon nitride layer is used as the insulating layer 160.

The conductive layers 180-1 and 180-2 are provided on the insulating layer 160. The conductive layer 180-1 is connected to the oxide semiconductor layer 130-1 via a contact hole CH1 provided in the insulating layer 160, and functions as a source electrode in the transistor Tr1. The conductive layer 180-2 is connected to the oxide semiconductor layer 130-1 via a contact hole CH2 provided in the insulating layer 160, and functions as a drain electrode in the transistor Tr1. In other words, the conductive layers 180-1 and 180-2 function as terminal electrodes in the transistor Tr1, respectively. Aluminum (Al), copper (Cu), titanium (Ti), molybdenum (Mo), tantalum (Ta) or tungsten (W), or an alloy thereof can be used as a material forming the conductive layers 180-1 and 180-2. In the present embodiment, a stacked structure including a titanium layer and an aluminum layer is used as a material forming the conductive layers 180-1 and 180-2.

As described above, the transistor Tr1 of the present embodiment is a dual-gate transistor including the lower-layer side gate electrode (the conductive layer 110-1) facing the oxide semiconductor layer 130-1 via the insulating layer 120, and the upper-layer side gate electrode (the conductive layer 150-1) facing the oxide semiconductor layer 130-1 via the insulating layer 140.

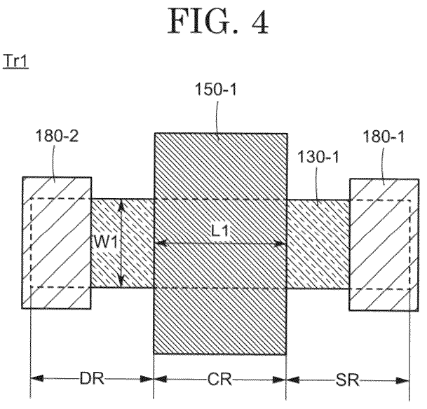

FIG. 4 is a schematic plan view showing a configuration of the transistor Tr1 of a semiconductor device according to an embodiment of the present invention. As shown in FIG. 4, the oxide semiconductor layer 130-1 is divided into a source region SR, a drain region DR, and a channel region CR based on the gate electrode (the conductive layer 150-1). The channel region CR is a region that overlaps the conductive layer 150-1, and the source region SR and drain region area DR are regions that do not overlap the conductive layer 150-1. The end portion of the channel region CR is substantially coincident with the end portion of the conductive layer 150-1. The source region SR and the drain region DR have a higher electrical conductivity than the channel region CR. The source region SR and the drain region DR have conductive properties, and the channel region has semiconductor properties. The source electrode (the conductive layer 180-1) and the drain electrode (the conductive layer 180-2) are in contact with the source region SR and the drain region DR, respectively.

As shown in FIG. 4, in the channel region CR, a length in a first direction connecting the source electrode and the drain electrode is referred to as a channel length (L1), and a length (width) in a direction perpendicular to the first direction is referred to as a channel width (W1). The channel length (L1) of the transistor Tr1 is a parameter related to the moving distance of carriers flowing through the channel region CR, and corresponds to a length between the source region SR and the drain region DR in a plan view. The channel width (W1) of the transistor Tr1 is a parameter related to the moving distance of carriers flowing through the channel region CR, and corresponds to a length in a direction perpendicular to the extending direction of the channel length (L1) in a plan view.

Next, a structure of the transistor Tr2 will be described. The transistor Tr2 includes a conductive layer 110-2, the oxide semiconductor layer 130-2, a conductive layer 135, the insulating layer 140, and a conductive layer 150-2 provided on the substrate 100 having an insulating surface.

The conductive layer 110-2 is provided on the substrate 100 and is the same layer as the conductive layer 110-1. That is, a material forming the conductive layer 110-2 is the same as that of the conductive layer 110-1. The conductive layer 110-2 functions as a terminal electrode (specifically, a source electrode or a drain electrode) in the transistor Tr2.

The oxide semiconductor layer 130-2 is provided to cover an opening OP provided in the insulating layer 120. Specifically, the oxide semiconductor layer 130-2 includes a portion positioned on the upper surface of the insulating layer 120 and a portion inside the opening OP. The oxide semiconductor layer 130-2 is the same layer as the oxide semiconductor layer 130-1. The oxide semiconductor layer 130-2 functions as an active layer in the transistor Tr2. Specifically, a portion of the oxide semiconductor layer 130-2 along the side walls of the opening OP functions as a channel of the transistor Tr2.

The conductive layer 135 is provided on the oxide semiconductor layer 130-2. Specifically, the conductive layer 135 is provided on a portion of the oxide semiconductor layer 130-2 positioned on the upper surface of the insulating layer 120. In other words, the conductive layer 135 is in contact with the upper surface of the oxide semiconductor layer 130-2. The conductive layer 135 functions as a terminal electrode (specifically, a source electrode or a drain electrode) in the transistor Tr2. Aluminum (Al), copper (Cu), titanium (Ti), molybdenum (Mo), tantalum (Ta) or tungsten (W), or an alloy thereof can be used as a material forming the conductive layer 135. In the present embodiment, a stacked structure including a titanium layer and an aluminum layer is used as the material forming the conductive layer 135. In the transistor Tr2, the conductive layer 135 is positioned between the oxide semiconductor layer 130-2 and the insulating layer 140.

The insulating layer 140 functions as a gate insulating layer in the transistor Tr2. Specifically, a portion of the insulating layer 140 along the side walls of the opening OP functions as a gate insulating layer of the transistor Tr2.

The conductive layer 150-2 is the same layer as the conductive layer 150-1. The conductive layer 150-2 functions as a gate electrode in the transistor Tr2. Specifically, a portion of the conductive layer 150-2 along the side walls of the opening OP functions as a gate electrode of the transistor Tr2.

In addition, the insulating layer 160 functioning as an interlayer insulating layer in the transistor Tr1 functions as a protective layer that covers the upper portion of the transistor Tr2 in the transistor Tr2.

As described above, the transistor Tr2 of the present embodiment has a structure in which the oxide semiconductor layer 130-2 and the conductive layer 150-2 face each other with the insulating layer 140 interposed therebetween on an inner side of the opening OP (specifically, the side walls of the opening OP) provided in the insulating layer 120. That is, as shown in FIG. 3, since the channel of the transistor Tr2 extends along the sidewalls of the opening OP in the longitudinal direction (a direction substantially perpendicular to the substrate 100), in the present embodiment, the transistor Tr2 is referred to as a vertical transistor.

In a cross-sectional view, a channel direction (a direction in which a current flows) of the transistor Tr2 is a direction that intersects with a channel direction of the transistor Tr1. In FIG. 3, a channel length (L2) of the transistor Tr2 is shown as the distance from the upper surface of the conductive layer 110-2 to the lower surface of the conductive layer 135, but substantially the channel length (L2) corresponds to the thickness of the insulating layer 120. Therefore, the channel length (L2) of the vertical transistor is smaller than the channel length (L1) of the dual-gate transistor (the transistor Tr1). As described above, since the oxide semiconductor layer 130-2 arranged on the side walls of the opening OP provided in the insulating layer 120 is used as the channel in the transistor Tr2, the channel length (L2) can be accurately controlled by controlling the thickness of the insulating layer 120.

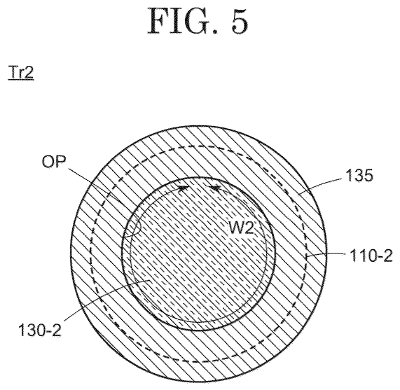

FIG. 5 is a schematic plan view showing a configuration of the transistor Tr2 of a semiconductor device according to an embodiment of the present invention. However, for convenience of explanation, the conductive layer 150-2 positioned above the conductive layer 135 is not illustrated in FIG. 5. As shown in FIG. 5, the oxide semiconductor layer 130-2 is provided not only on the bottom surface of the opening OP but also along the side walls (side surfaces) of the opening OP. Therefore, a channel width (W2) of the transistor Tr2 generally corresponds to the inner circumference of the opening OP. In this way, the channel width (W2) of the transistor Tr2 can be set according to the size of the outer shape of the opening OP. Therefore, the transistor Tr2 can have a channel width (W1) larger than that of the transistor Tr1 while reducing the occupied area.

In addition, as shown in FIG. 5, although the case where the planar shape of the opening OP is circular has been exemplified, the planar shape of the opening OP is not limited to this. The planar shape of the opening OP may be elliptical or polygonal. In addition, the oxide semiconductor layer 130-2 may be provided not on the entire side walls of the opening OP but on a portion of the side walls of the opening OP.

As shown in FIG. 3 and FIG. 5, in a plan view, the conductive layer 110-2 is arranged at a position overlapping the opening OP, and is in contact with the lower surface of the oxide semiconductor layer 130-2 inside the opening OP. Further, in a plan view, the conductive layer 135 is arranged to be in contact with the upper surface of the oxide semiconductor layer 130-2 outside the opening OP. In this case, the conductive layer 110-2 and the conductive layer 135 function as the source electrode or the drain electrode of the second transistor Tr2, so that the portions of the oxide semiconductor layer 130-2 along the side walls of the opening OP function as a channel.

As described above, in the display device 10 of the present embodiment, a semiconductor device (specifically, a semiconductor circuit) including the transistor Tr1 which is a dual-gate transistor and the transistor Tr2 which is a vertical transistor is arranged in each pixel 13. The semiconductor device forms a part of the pixel circuit for driving the light-emitting element OLED. As shown in FIG. 5, the vertical transistor has a very small footprint (i.e., occupied area) because the channel is formed in the thickness direction of the insulating layer 120 and the channel width is determined by the inner circumference of the opening OP. Therefore, as in the present embodiment, by using a vertical transistor as the select transistor SST, a semiconductor device using the oxide semiconductor can be highly integrated, and a high-definition display portion 12 can be realized.

Referring back to FIG. 3, an insulating layer 190 is provided as a planarization layer formed of a resin material on the transistor Tr1 and the transistor Tr2. The pixel electrode 200 is connected to the conductive layer 180-1 (that is, the source electrode of the transistor Tr1) via a contact hole CH3 provided in the insulating layer 190. In the present embodiment, a stacked structure of a layer containing silver (Ag) and a layer containing a metal oxide (for example, ITO) is used as the pixel electrode 200, but the present invention is not limited to this.

A bank 210 composed of a resin is provided on the pixel electrode 200. The bank is also referred to as a barrier or a rib. The bank 210 is provided to cover a portion of the pixel electrode 200. In other words, the bank 210 has an opening 212 at a position overlapping the pixel electrode 200. A region (exposed region) of the pixel electrode 200 that is not covered with the bank 210 functions as a light-emitting region of the pixel 13. A light-emitting layer 220 composed of an organic EL (electroluminescence) material is provided to cover the exposed region of the pixel electrode 200.

Further, the common electrode 230 is provided to cover the bank 210 and the light-emitting layer 220. Although not illustrated in FIG. 3, the common electrode 230 is arranged across the plurality of pixels 13. The pixel electrode 200, the light-emitting layer 220, and the common electrode 230 form the light-emitting element OLED. The pixel electrode 200 functions as the anode of the light-emitting element OLED. The common electrode 230 functions as the cathode of the light-emitting element OLED.

A sealing layer 240 is provided on the light-emitting element OLED. The sealing layer 240 is a protective layer for preventing intrusion of moisture or the like from the outside. In the present embodiment, a stacked structure in which an inorganic insulating layer, an organic insulating layer, and an inorganic insulating layer are stacked in this order from the lower layer is used as the sealing layer 240. For example, a silicon nitride layer can be used as the inorganic insulating layer. For example, an organic resin layer (for example, a resin layer composed of polyimide or acryl) can be used as the organic insulating layer.

In the pixel 13 described above, a dual-gate transistor is used as the drive transistor DRT (transistor Tr1) for adjusting the amount of current flowing through the light-emitting element OLED. In addition, a vertical transistor is used as the select transistor SST (transistor Tr2) used in a switching operation for applying a voltage corresponding to the video signal Vsig to the gate of the drive transistor DRT. As described above, in the present embodiment, different types of transistors can be used as the drive transistor DRT and the select transistor SST, respectively. Therefore, in the display device 10 of the present embodiment, the transistor characteristics can be set according to the specifications of the drive transistor DRT and the specifications of the select transistor SST.

Typically, the device characteristics of a transistor vary depending on the thickness of the gate insulating layer and the length of the channel (channel length). Therefore, by appropriately setting the thickness of the gate insulating layer and the channel length, an on-state current (a current that flows when the transistor is in the on-state) can be increased, and a sub-threshold swing value (hereinafter referred to as “S value”) can be improved. In particular, decreasing the S value means shortening a transition period from an off-state to the on-state of the transistor, that is, improving the switching characteristics. The select transistor SST described above is required to have a large on-state current and a steep rise in the switching characteristics as the device characteristics. Therefore, it is desirable to use a transistor that easily allows a large current to flow through and has excellent switching characteristics as the select transistor SST.

On the other hand, the drive transistor DRT is required to have a large on-state current as the device characteristics, but does not need a steep rise in the switching characteristics. In the drive transistor DRT, the amount of current flowing through the channel is controlled by the voltage applied to the gate, so that a change in the gate voltage appears as a change in the amount of current. In this case, when the S value of the drive transistor DRT is small (i.e., in the switching characteristics, the transition period is short from the off-state to the on-state), a problem occurs in that the amount of current flowing through the channel greatly changes due to a slight change in the gate voltage. In particular, in a low gradation region that needs to be controlled with a small current, fine gradation control becomes difficult due to a large change in the amount of current flowing through the channel, and there is a risk that uneven display may easily occur in the display portion 12.

As described above, since the device characteristics required for the drive transistor DRT and the select transistor SST are different in the display device 10, it is desirable to appropriately use transistors having different device characteristics. Taking this into consideration, in the present embodiment, a dual-gate transistor is used as the drive transistor DRT, and a vertical transistor is used as the select transistor SST.

Since the channel length (L2) of the vertical transistor is substantially determined by the thickness of the insulating layer 120, the channel length (L2) of the select transistor SST (transistor Tr1) can be adjusted by controlling the thickness of the insulating layer 120. In the present embodiment, the thickness of the insulating layer 120 is set to 100 nm or more and 1000 nm or less (preferably 200 nm or more and 900 nm or less, more preferably 300 nm or more and 800 nm or less). In other words, the channel length (L2) of the select transistor SST can be set to 100 nm or more and 1000 nm or less (preferably 200 nm or more and 900 nm or less, and more preferably 300 nm or more and 800 nm or less).

On the other hand, in the drive transistor DRT (the transistor Tr1), the insulating layer 120 functions as a lower-layer side gate insulating layer. In the present embodiment, since the drive transistor DRT is a dual-gate transistor, the transistor characteristics are not determined only by the thickness of the insulating layer 120. However, by increasing the thickness of the insulating layer 120, it is possible to adjust the switching characteristics of the drive transistor DRT to be reduced (i.e., the S value can be increased).

Further, in the present embodiment, the thickness of the insulating layer 140 that functions as the gate insulating layer on the upper-layer side of the drive transistor DRT (transistor Tr1) is set to 50 nm or more and 300 nm or less (preferably 60 nm or more and 200 nm or less, and more preferably 70 nm or more and 300 nm or less). The insulating layer 140 functions as a gate insulating layer in the select transistor SST (transistor Tr2).

In the present embodiment, by setting the thicknesses of the insulating layers 120 and 140 as described above, the transistor Tr2 having excellent switching characteristics and the transistor Tr1 having a larger S value than the transistor Tr2 can be arranged in the same pixel 13. As described above, in the display device 10 of the present embodiment, different types of transistors using the oxide semiconductor are formed on the same substrate, so that the characteristics of the individual transistors forming the semiconductor device using the oxide semiconductor can be made different.

### Method for Manufacturing Semiconductor Device

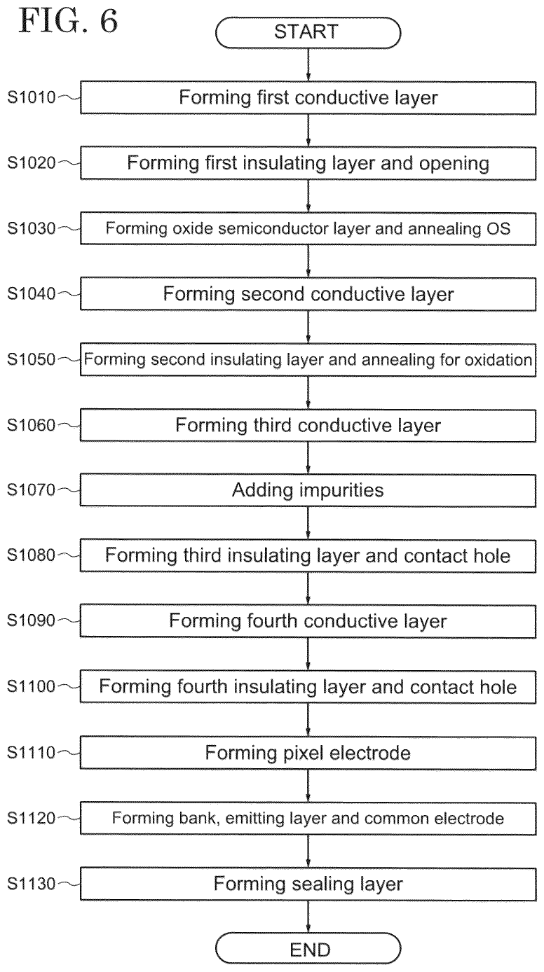

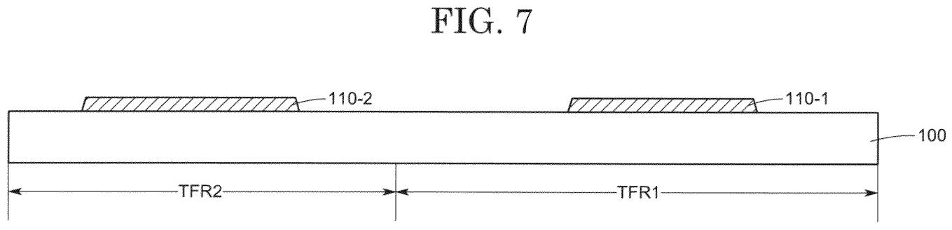

FIG. 6 is a flowchart for explaining a method for manufacturing the pixel 13 including a semiconductor device according to an embodiment of the present invention. FIG. 7 to FIG. 19 are schematic cross-sectional views showing a method for manufacturing the pixel 13 including a semiconductor device according to an embodiment of the present invention. As shown in FIG. 6, the method for manufacturing the semiconductor device of the present embodiment includes steps S1010 to S1130. Hereinafter, the steps S1010 to S1130 will be described in order, but the order of the steps may be changed in the method for manufacturing the semiconductor device of the present embodiment. Further, in the method for manufacturing the semiconductor device of the present embodiment, one or a plurality of steps may be omitted, or further steps may be included. In the following explanation, for convenience of explanation, a region where the transistor Tr1 is formed is referred to as a transistor forming region TFR1, and a region where the transistor Tr2 is formed is referred to as a transistor forming region TFR2.

First, as shown in FIG. 6 and FIG. 7, in the transistor forming region TFR1, the conductive layers 110-1 and 110-2 having a predetermined pattern shape are formed on the substrate 100 (step S1010). Patterning of the conductive layers 110-1 and 110-2 is performed using photolithography.

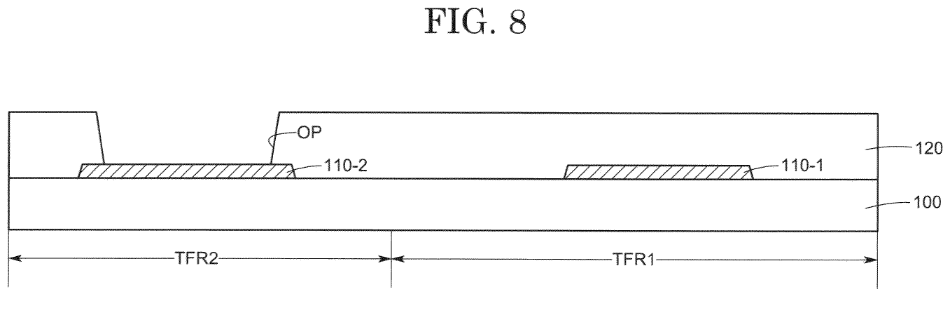

Next, as shown in FIG. 6 and FIG. 8, the insulating layer 120 is formed to cover the conductive layers 110-1 and 110-2. The insulating layer 120 is deposited using a chemical vapor deposition (CVD) method. After that, in the transistor forming region TFR2, an opening OP is formed in the insulating layer 120 to overlap the conductive layer 110-2 (step S1020).

The opening OP is formed by patterning the insulating layer 120 using photolithography. As shown in FIG. 8, the opening OP is formed to overlap the conductive layer 110-2. As a result, a portion of the upper surface of the conductive layer 110-2 is exposed by the opening OP.

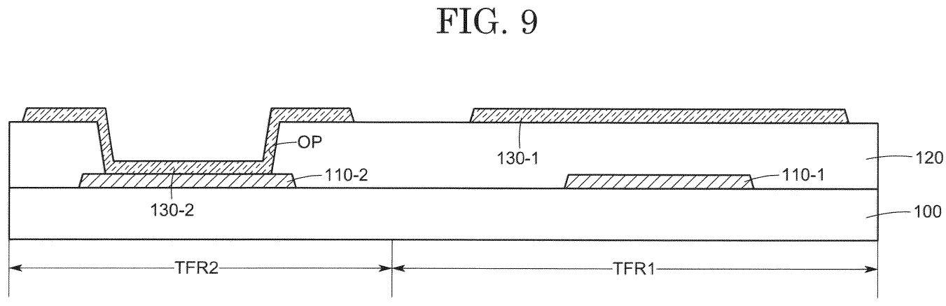

Next, as shown in FIG. 6 and FIG. 9, the oxide semiconductor layers 130-1 and 130-2 having a predetermined pattern shape are formed on the insulating layer 120 (step S1030). The oxide semiconductor layer 130-1 is formed to overlap the conductive layer 110-1 in the transistor forming region TFR1. The oxide semiconductor layer 130-2 is formed to cover the opening OP in the transistor forming region TFR2. Specifically, the oxide semiconductor layer 130-2 is formed not only on a portion of the upper surface of the insulating layer 120, but also inside the opening OP to be in contact with the side walls of the opening OP and the upper surface of the conductive layer 110-2.

The oxide semiconductor layers 130-1 and 130-2 are formed by patterning an oxide semiconductor film deposited by the sputtering method into predetermined shapes using photolithography. The oxide semiconductor film deposited by the sputtering method has an amorphous structure. In the case where the oxide semiconductor film is deposited using the sputtering method, the oxide semiconductor film is preferably deposited while controlling the temperature of an object to be deposited (the substrate 100 and layers formed on the substrate 100) to 100° C. or lower (preferably 80° C. or lower, more preferably 50° C. or lower). In addition, it is also preferable to form the oxide semiconductor film under conditions of low-oxygen partial pressure. For example, the oxygen partial pressure is preferably 2% or more and 20% or less (preferably 3% or more and 15% or less, more preferably 3% or more and less than 10%).

The oxide semiconductor film having an amorphous structure can be easily patterned using photolithography. When etching the oxide semiconductor film, either wet etching or dry etching may be used. When wet etching is used, the oxide semiconductor film can be etched using an acid etching solution. For example, an oxalic acid solution, a PAN (mixed acid of phosphoric acid, nitric acid, and acetic acid), a sulfuric acid solution, a hydrogen peroxide solution, or a hydrofluoric acid solution can be used as the etching solution.

In addition, a heat treatment is performed on the oxide semiconductor layers 130-1 and 130-2 having a predetermined pattern shape. Hereinafter, the heat treatment performed in the step S1030 is referred to as “OS annealing”. In the OS annealing process, the oxide semiconductor layers 130-1 and 130-2 are maintained at a predetermined reaching temperature for a predetermined time. The predetermined reaching temperature is 300° C. or higher and 500° C. or lower (preferably 350° C. or higher and 450° C. or lower). In addition, the holding time at the reaching temperature is 15 minutes or more and 120 minutes or less (preferably 30 minutes or more and 60 minutes or less).

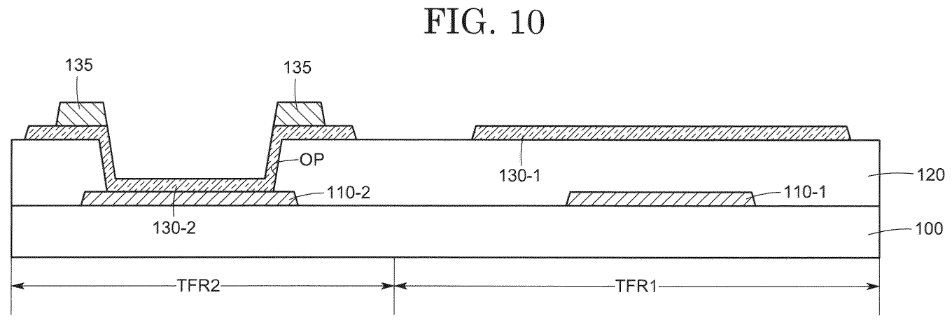

Next, as shown in FIG. 6 and FIG. 10, a second conductive layer (the conductive layer 135) is formed on the oxide semiconductor layer 130-2 (step S1040). The conductive layer 135 is formed by depositing a metal layer containing aluminum (Al), copper (Cu), titanium (Ti), molybdenum (Mo), tantalum (Ta) or tungsten (W), or an alloy thereof, and then patterning the metal layer into a predetermined pattern shape.

The conductive layer 135 is formed on a portion of the oxide semiconductor layer 130-2 that is positioned on the upper surface of the insulating layer 120. Specifically, the conductive layer 135 is formed on the oxide semiconductor layer 130-2 to surround the opening OP in a plan view. The conductive layer 135 is paired with the conductive layer 110-2 and functions as a terminal electrode (source electrode or drain electrode) of the transistor Tr2.

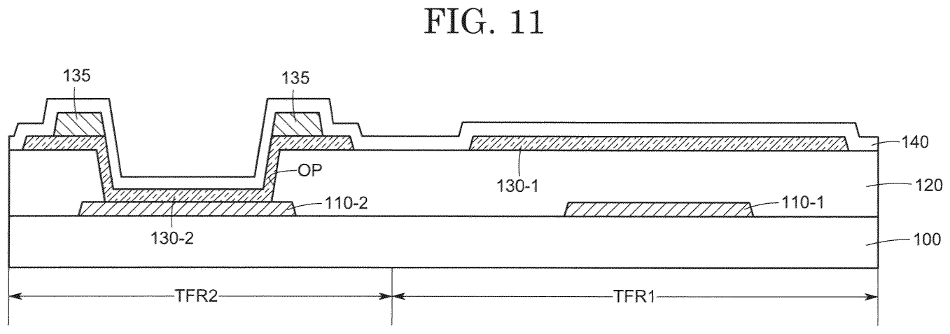

Next, as shown in FIG. 6 and FIG. 11, a second insulating layer (the insulating layer 140) is formed on the oxide semiconductor layers 130-1 and 130-2 and the conductive layer 135 (step S1050). In the present embodiment, a silicon oxide layer having a thickness of 150 nm is used as the insulating layer 140. In addition, the heat treatment is performed on the insulating layer 140. Hereinafter, the heat treatment performed in the step S1050 is referred to as “oxidation annealing”. By forming the oxide semiconductor layers 130-1 and 130-2 and forming the insulating layer 140, many oxygen defects are generated inside the oxide semiconductor layers 130-1 and 130-2. When oxidation annealing is performed, oxygen is supplied from the insulating layer 140 to the oxide semiconductor layers 130-1 and 130-2, and oxygen defects in the oxide semiconductor layers 130-1 and 130-2 are repaired.

In the present embodiment, an example has been shown in which the insulating layer 140 is formed and then oxidation annealing is performed in that state, but a process of introducing oxygen into the insulating layer 140 may be performed before the oxidation annealing process. For example, an aluminum oxide layer may be formed on the insulating layer 140 by the sputtering method, and oxidation annealing may be performed in the state in which the aluminum oxide layer is formed. In this case, oxygen is implanted into the insulating layer 140 to increase the amount of oxygen in the insulating layer 140 at the time of forming the aluminum oxide layer, so that a sufficient amount of oxygen can be supplied to the oxide semiconductor layers 130-1 and 130-2 by the oxidation annealing process.

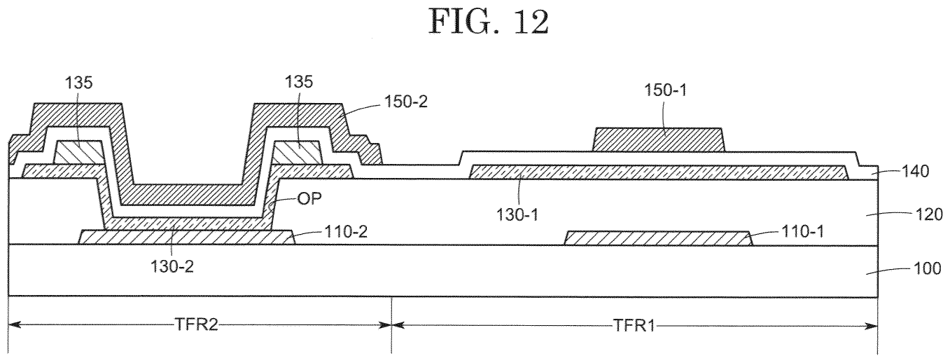

Next, as shown in FIG. 6 and FIG. 12, a third conductive layer (the conductive layers 150-1 and 150-2) is formed on the insulating layer 140 (step S1060). In the present embodiment, the conductive layers 150-1 and 150-2 are formed by forming a metal film composed of a molybdenum-tungsten alloy using the sputtering method and patterning the metal film into a predetermined shape. In the present embodiment, the thickness of the conductive layers 150-1 and 150-2 is 300 nm, but the present invention is not limited to this.

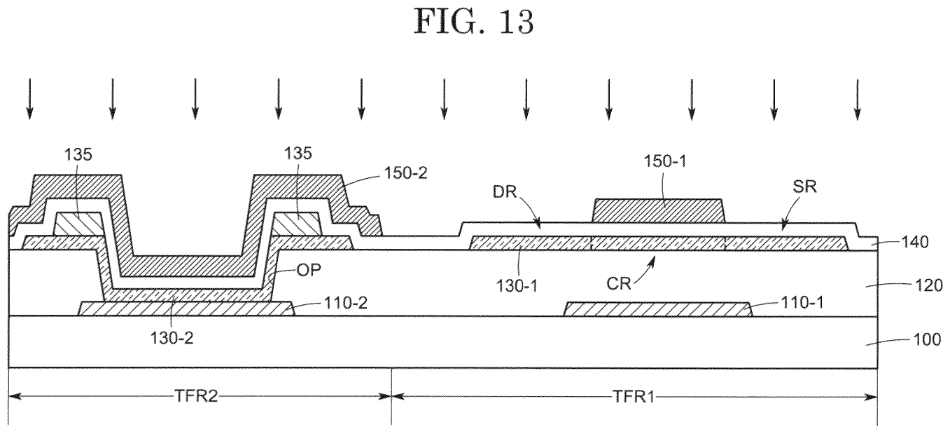

Next, as shown in FIG. 6 and FIG. 13, an impurity is implanted into the oxide semiconductor layer 130-1 via the insulating layer 140 (step S1070). For example, the impurity can be implanted into the oxide semiconductor layer 130-1 using an ion-implantation method. For example, argon (Ar), phosphorus (P), or boron (B) can be used as the impurity. However, the present invention is not limited to this example, and other elements may be used.

In the transistor forming region TFR1, the conductive layer 150-1 is formed on the oxide semiconductor layer 130-1, so that the conductive layer 150-1 functions as a mask, and the implantation of the impurity into the oxide semiconductor layer 130-1 is inhibited. Therefore, in the oxide semiconductor layer 130-1, the impurity is not implanted into the region overlapping the conductive layer 150-1, and the channel region CR is formed in that region. Further, the source region SR and the drain region DR are formed in a region of the oxide semiconductor layer 130-1 where the impurity is implanted because the region does not overlap the conductive layer 150-1. In the source region SR and the drain region DR, oxygen defects are generated by the implantation of the impurity, and hydrogen is trapped in the oxygen defects. As a result, the source region SR and the drain region DR are electrically conductive and have higher electric conductivity than the channel region CR.

On the other hand, in the transistor forming region TFR2, since the conductive layer 150-2 covers the entire oxide semiconductor layer 130-2, impurities are not implanted into the oxide semiconductor layer 130-2. Therefore, the entire oxide semiconductor layer 130-2 is composed of the oxide semiconductor in the same condition as the channel region CR of the oxide semiconductor layer 130-1.

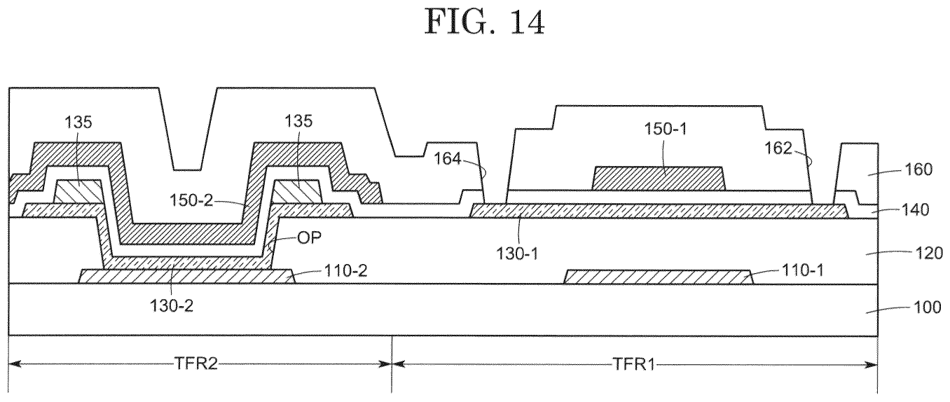

Next, as shown in FIG. 6 and FIG. 14, a third insulating layer (the insulating layer 160) is formed to cover the conductive layers 150-1 and 150-2 (step S1080). In the present embodiment, the insulating layer 160 having a stacked structure in which a silicon oxide layer and a silicon nitride layer are stacked in this order from the lower layer is formed by a plasma CVD method. Contact holes 162 and 164 are formed in portions of the insulating layers 140 and 160 that overlap the source region SR and the drain region DR of the oxide semiconductor layer 130-1, respectively.

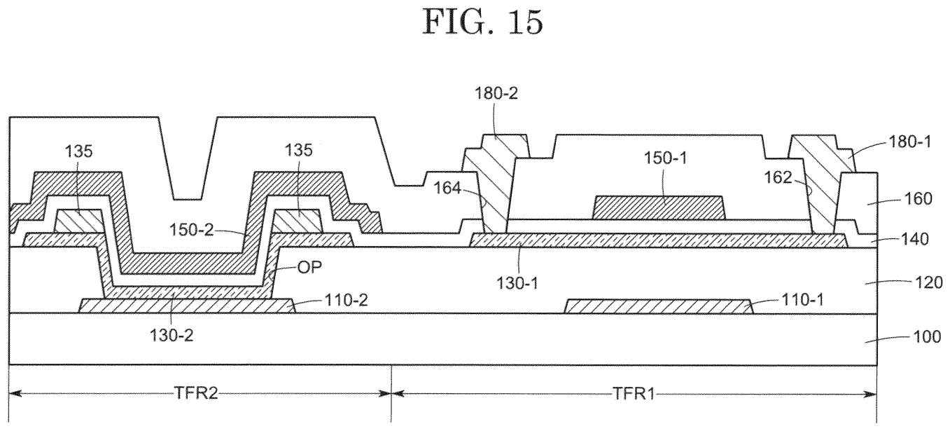

Next, as shown in FIG. 6 and FIG. 15, a fourth conductive layer (the conductive layers 180-1 and 180-2) is formed on the insulating layer 160 (step S1090). Specifically, the conductive layers 180-1 and 180-2 are formed by forming a three-layer metal layer composed of a titanium layer, an aluminum layer, and a titanium layer in this order by the sputtering method, and patterning the metal layer into a predetermined shape. The conductive layers 180-1 and 180-2 are electrically connected to the oxide semiconductor layer 130-1 via the contact holes 162 and 164, respectively. That is, the conductive layer 180-1 functions as a source electrode, and the conductive layer 180-2 functions as a drain electrode.

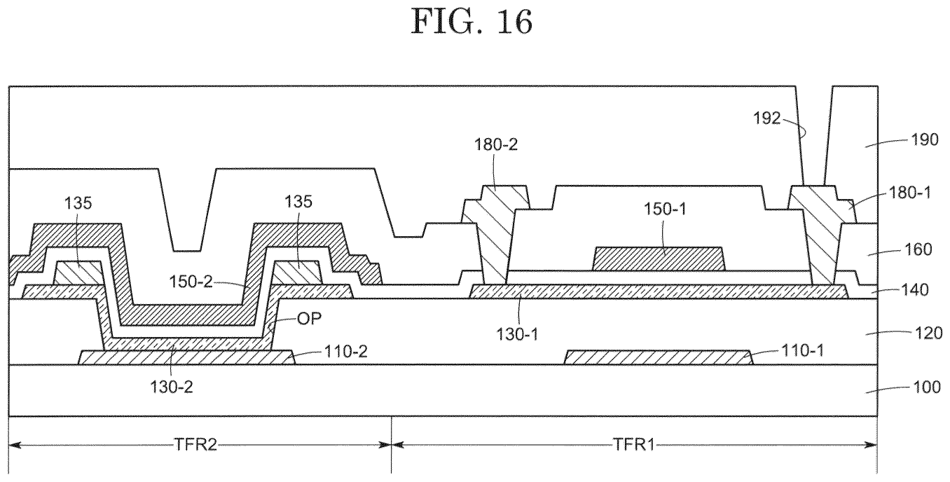

Next, as shown in FIG. 6 and FIG. 16, a fourth insulating layer (the insulating layer 190) is formed to cover the conductive layers 180-1 and 180-2 (step S1100). The insulating layer 190 of the present embodiment is formed by applying a resin material (for example, acryl or polyimide) by a solution-coating method. In the present embodiment, a photosensitive acryl material is used as the insulating layer 190. The insulating layer 190 having a contact hole 192 can be formed by performing exposure and photolithography using a photosensitive resin-material. In the present embodiment, the contact hole 192 is formed in a portion of the insulating layer 190 overlapping the conductive layer 180-1.

In the present embodiment, although an example in which the insulating layer 190 is formed by the solution-coating method has been shown, the present invention is not limited to this example, and may be formed by other methods, such as a printing method. The insulating layer 190 functions as a planarization layer. Therefore, the thickness of the insulating layer 190 is preferably 1 μm or more and 4 μm or less (preferably 2 μm or more and 3 μm or less).

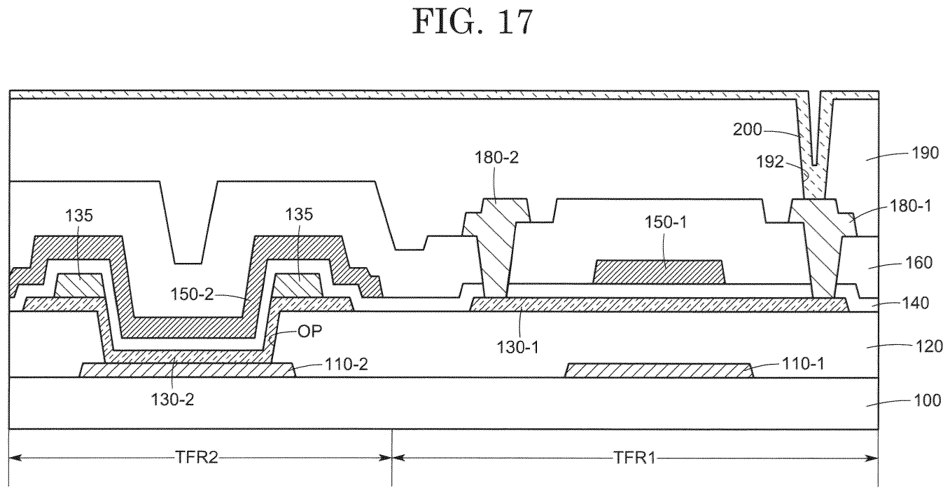

Next, as shown in FIG. 6 and FIG. 17, the pixel electrode 200 is formed on the insulating layer 190 (step S1110). Specifically, a transparent conductive film (metal oxide film) is formed on the insulating layer 190 by the sputtering method, and is patterned into a predetermined pattern shape to form the pixel electrode 200. In the present embodiment, ITO (indium tin oxide), which is a metal oxide, is used as a material forming the pixel electrode 200. The pixel electrode 200 is electrically connected to the conductive layer 180-2 functioning as a source electrode via the contact hole 192.

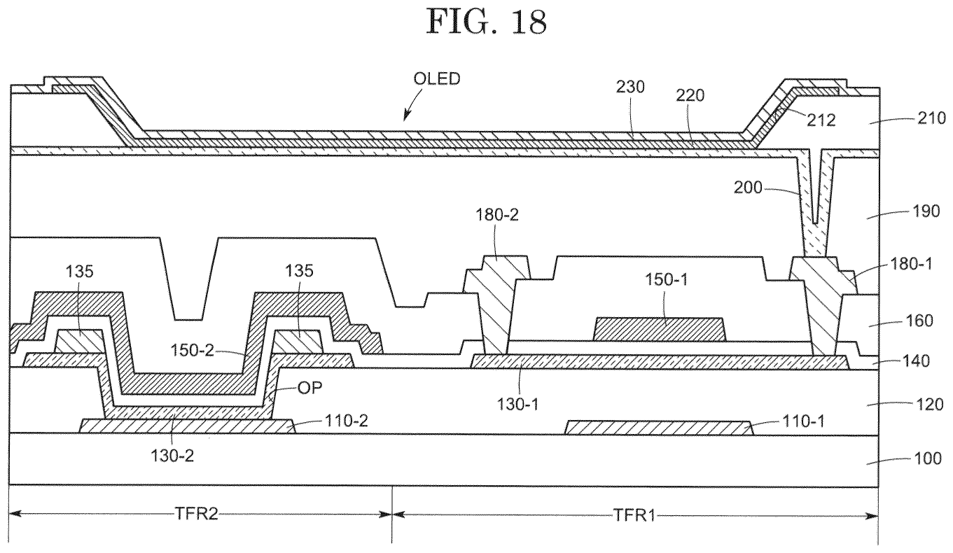

Next, as shown in FIG. 6 and FIG. 18, the bank 210 is formed on the pixel electrode 200 (step S1120). A resin material (for example, a photosensitive acrylic material) can be used as a material forming the bank 210. Specifically, the resin material is applied by the solution coating method or the like, and then the bank 210 including the opening 212 is formed by performing exposure and development. As shown in FIG. 18, the opening 212 provided in the bank 210 exposes most of the upper surface of the pixel electrode 200.

After the bank 210 is formed, the light-emitting layer 220 composed of an organic EL material is formed to overlap the opening 212. In the present embodiment, an organic EL that emits red, green, or blue light is formed as the light-emitting layer 220 by a vapor deposition method. The light-emitting layer 220 is formed to emit light of different colors for each pixel 13. That is, an organic EL material that emits red is used for the pixel 13 that emits red, an organic EL material that emits green is used for the pixel 13 that emits green, and an organic EL material that emits blue is used for the pixel 13 that emits blue. The light-emitting layer 220 may include, in addition to a light-emitting layer composed of a light-emitting material, an electron injection layer, an electron transport layer, an electron blocking layer, a hole injection layer, a hole transport layer, or a hole blocking layer as a functional layer composed of a functional material.

The common electrode 230 is formed on the light-emitting layer 220. In the present embodiment, a layer containing magnesium silver is formed as the common electrode 230 by the vapor deposition method. The common electrode 230 may be provided across the plurality of pixels. By forming the common electrode 230, the light-emitting element OLED composed of the pixel electrode 200, the light-emitting layer 220, and the common electrode 230 is formed.

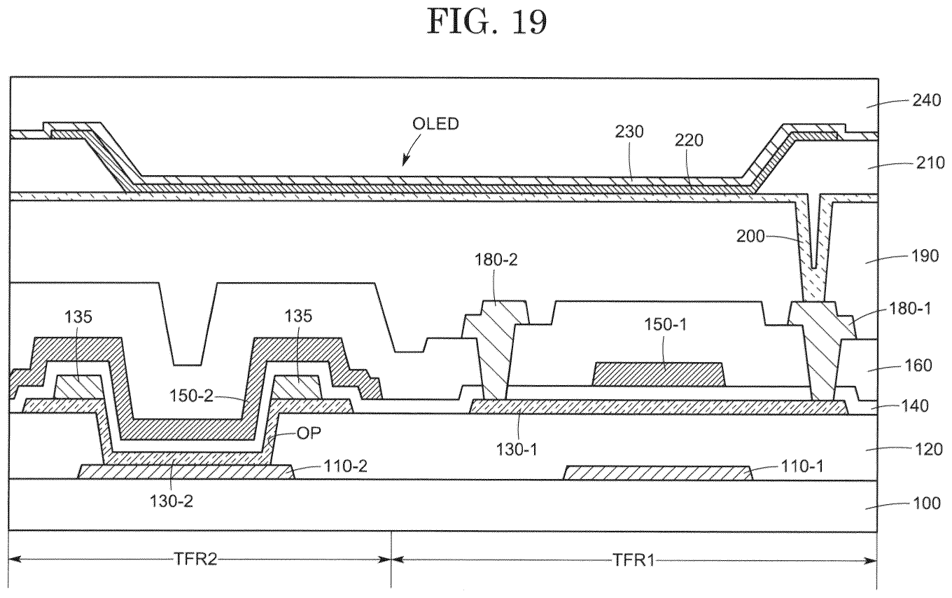

Finally, as shown in FIG. 6 and FIG. 19, the sealing layer 240 is formed to cover the light-emitting element OLED (step S1130). Although not shown, the sealing layer 240 has a stacked structure in which a silicon nitride layer, an organic resin layer (for example, an acryl layer), and a silicon nitride layer are stacked in this order from the lower layer. However, the present invention is not limited to this example, and a silicon oxide layer or an amorphous silicon layer may be provided between the silicon nitride layer and the organic resin layer. By providing these layers, adhesion between the silicon nitride layer and the organic resin layer can be improved. In addition, since the touch sensor 20 (see FIG. 1) is provided on the sealing layer 240 in the present embodiment, an overcoat layer may be provided on the sealing layer 240 for planarization.

Through the above-described process, a semiconductor device including the transistors Tr1 and Tr2 in each pixel 13 is completed. In the present embodiment, the transistor Tr1, which is a dual-gate transistor, and the transistor Tr2, which is a vertical transistor, are formed on the same substrate by the same process. That is, according to the present embodiment, since transistors having completely different structures can be formed by the same process, the degree of freedom in circuit design can be improved.

### Modification

In the present embodiment, although an example in which the transistor Tr1 is used as a dual-gate transistor has been described, the present invention is not limited to this example. For example, the transistor Tr1 can be used as a top-gate transistor or a bottom-gate transistor.

In the case where the transistor Tr1 is used as a top-gate transistor, in FIG. 3, only the conductive layer 150-1 may function as a gate electrode without causing the conductive layer 110-1 to function as a gate electrode. Specifically, the transistor Tr1 can be operated as a top-gate transistor by putting the conductive layer 110-1 into a floating state (a state in which no voltage is applied) or applying a predetermined fixed voltage to the conductive layer 110-1.

In the case where the transistor Tr1 is used as a bottom-gate transistor, in FIG. 3, only the conductive layer 110-1 may function as a gate electrode without causing the conductive layer 150-1 to function as a gate electrode. Specifically, the transistor Tr1 can be operated as a bottom-gate transistor by putting the conductive layer 150-1 into a floating state (a state in which no voltage is applied) or applying a predetermined fixed voltage to the conductive layer 150-1.

In the present embodiment, since the transistor Tr1 is used as the transistor DRT in the display device 10, it is preferable that the S value of the transistor Tr1 is relatively larger than that of the transistor Tr2. From this viewpoint, it can be said that it is preferable for the transistor Tr1 to function as a bottom-gate transistor. This is because, as shown in FIG. 3, the insulating layer 140 functions as a gate insulating layer of the transistor Tr2, and increasing the thickness is disadvantageous in increasing the on-state current of the transistor Tr2. On the other hand, increasing the thickness of the insulating layer 120 advantageously increases the on-state current of the transistor Tr2 because it increases the channel length (L2) of the transistor Tr2.

### Second Embodiment

In the first embodiment, an example in which a dual-gate transistor is used as the drive transistor DRT (transistor Tr1) arranged in each pixel 13 of the display device 10 has been described, but in the present embodiment, an example in which a bottom-gate transistor is used as the drive transistor DRT will be described. In the description of the present embodiment, the same elements as those of the first embodiment are denoted by the same reference signs in the drawings, and the description thereof may be omitted.

### Structure of Pixel

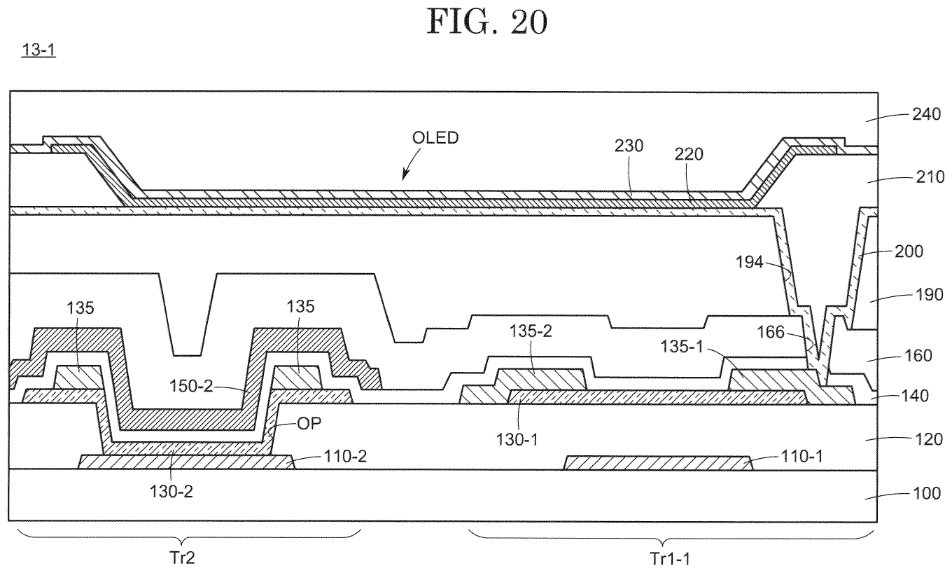

FIG. 20 is a schematic cross-sectional view showing a configuration of a semiconductor device according to an embodiment of the present invention. Similar to the first embodiment, the semiconductor device shown in FIG. 20 is arranged in each pixel 13-1 and is a semiconductor circuit including at least a transistor Tr1-1 and the transistor Tr2. The transistor Tr1-1 is a bottom-gate transistor.

The transistor Tr1-1 of the present embodiment includes the conductive layer 110-1, the insulating layer 120, the oxide semiconductor layer 130-1, and conductive layers 135-1 and 135-2 provided on the substrate 100 having an insulating surface. The configurations of the conductive layer 110-1, the insulating layer 120, and the oxide semiconductor layer 130-1 are the same as those of the first embodiment. The transistor Tr1-1 includes the conductive layer 135-1 as a source electrode and the conductive layer 135-2 as a drain electrode. The pixel electrode 200 is electrically connected to the conductive layer 135-1.

The conductive layers 135-1 and 135-2 are the same layer as the conductive layer 135 forming the source electrode or the drain electrode of the transistor Tr2. That is, the conductive layers 135-1 and 135-2 are positioned between the oxide semiconductor layer 130-1 and the insulating layer 140. The conductive layers 135-1 and 135-2 are simultaneously formed when forming the conductive layer 135 and have a predetermined pattern shape.

The insulating layers 140 and 160 function as an interlayer insulating layer of the transistor Tr1-1. In particular, the insulating layer 140 is an insulating layer that functions as a gate insulating layer of the transistor Tr2, and also functions as a protective layer that protects the channel portion of the transistor Tr1-1. As will be described later, the insulating layer 140 also serves to supply oxygen to the oxide semiconductor layer 130-1 during the oxidation annealing process to repair oxygen defects inside the oxide semiconductor layer 130-1.

### Method for Manufacturing Semiconductor Device

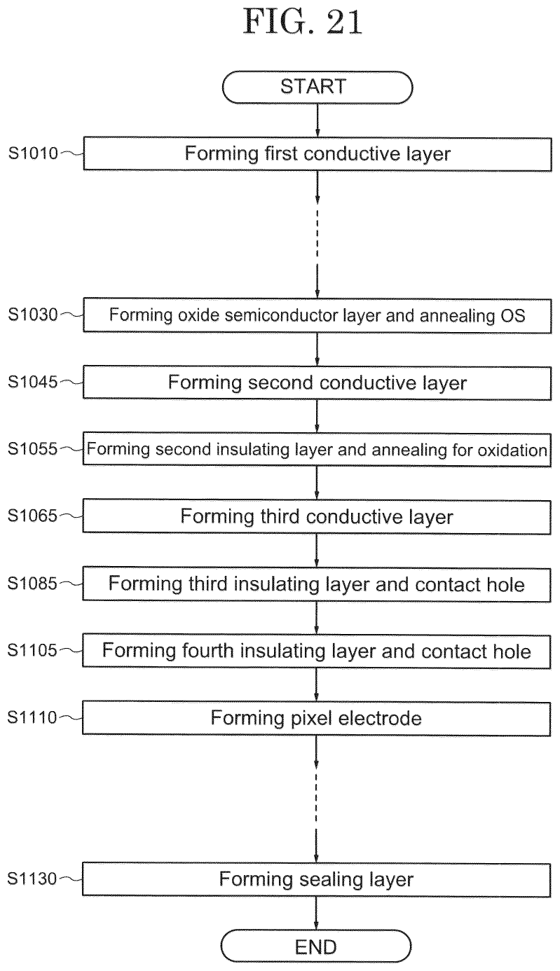

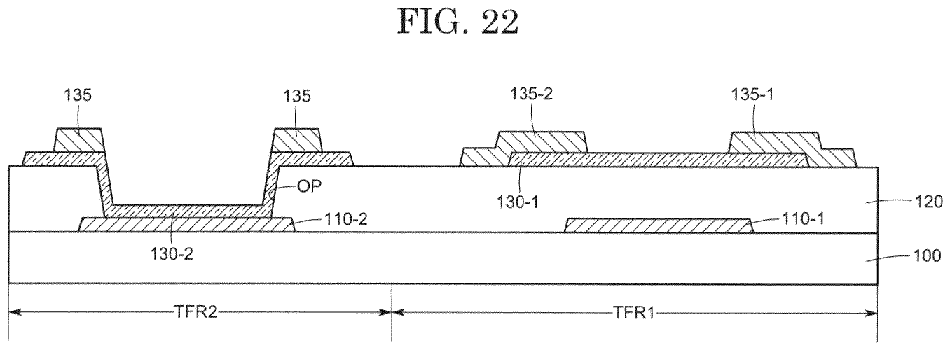

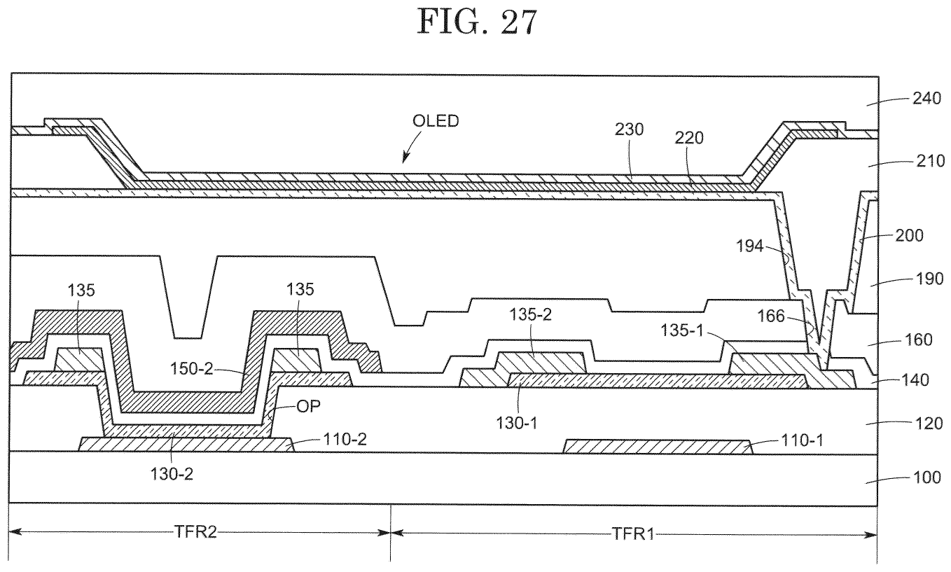

FIG. 21 is a flowchart for explaining a method for manufacturing the pixel 13-1 including a semiconductor device according to an embodiment of the present invention. FIG. 22 to FIG. 27 are schematic cross-sectional views showing a method for manufacturing the pixel 13-1 including a semiconductor device according to an embodiment of the present invention. Similar to the first embodiment, the order of the steps in the flowchart shown in FIG. 21 may be changed. Further, in the method for manufacturing the semiconductor device of the present embodiment, one or a plurality of steps may be omitted, or further steps may be included.

First, the steps S1010 to S1030 are executed according to the flowchart of FIG. 6 described in the first embodiment. At this point, as shown in FIG. 9, the oxide semiconductor layers 130-1 and 130-2 are formed.

Next, as shown in FIG. 21 and FIG. 22, the second conductive layer is formed on the oxide semiconductor layers 130-1 and 130-2 (step S1045). Specifically, the conductive layers 135-1 and 135-2 are formed on the oxide semiconductor layer 130-1, and the conductive layer 135 is formed on the oxide semiconductor layer 130-2. As described above, in the present embodiment, in forming the second conductive layer shown in the step S1045, in addition to the conductive layer 135, the conductive layers 135-1 and 135-2 are also formed. The conductive layers 135-1 and 135-2 are formed to overlap a portion that functions as a source region and a drain region in the oxide semiconductor layer 130-1, which forms the active layer of the transistor Tr1-1.

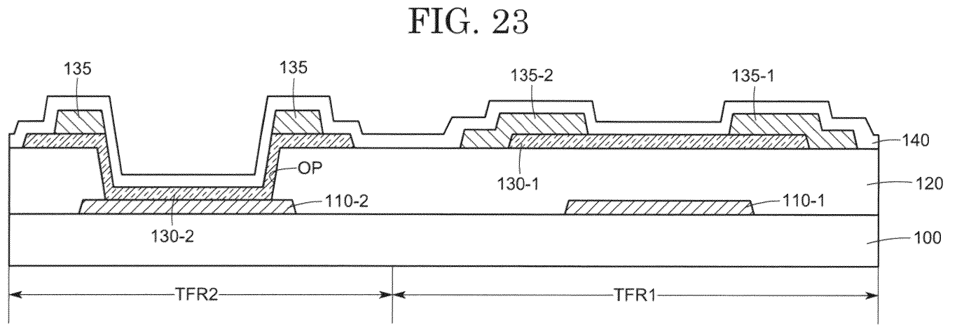

Next, as shown in FIG. 21 and FIG. 23, the second insulating layer (the insulating layer 140) is formed on the oxide semiconductor layers 130-1 and 130-2 and the conductive layers 135, 135-1, and 135-2 (step S1055). Further, the heat treatment (oxidation annealing) is performed on the insulating layer 140. Since this step is similar to the step S1050 shown in FIG. 6 in the first embodiment, a detailed explanation thereof will be omitted.

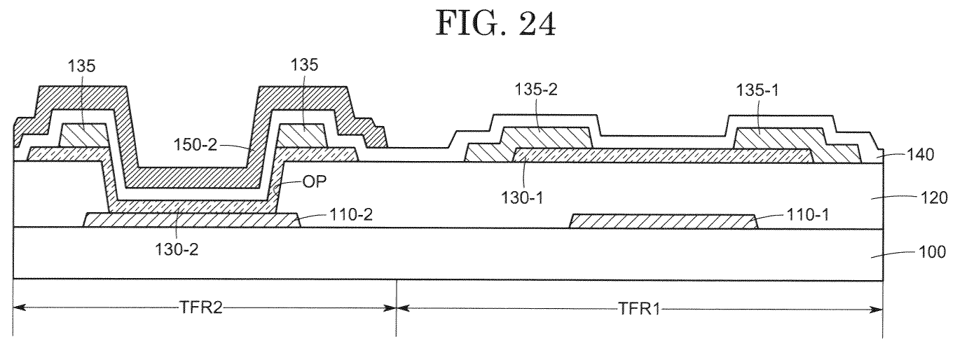

Next, As shown in FIG. 21 and FIG. 24, the third conductive layer (the conductive layer 150-2) is formed on the insulating layer 140 (step S1065). In the present embodiment, unlike the first embodiment, the third conductive layer (the conductive layer 150-2) is formed only in the transistor forming region TFR2, and the third conductive layer is not formed in the transistor forming region TFR1. Since this step is similar to the step S1060 shown in FIG. 6 in the first embodiment, a detailed explanation thereof will be omitted.

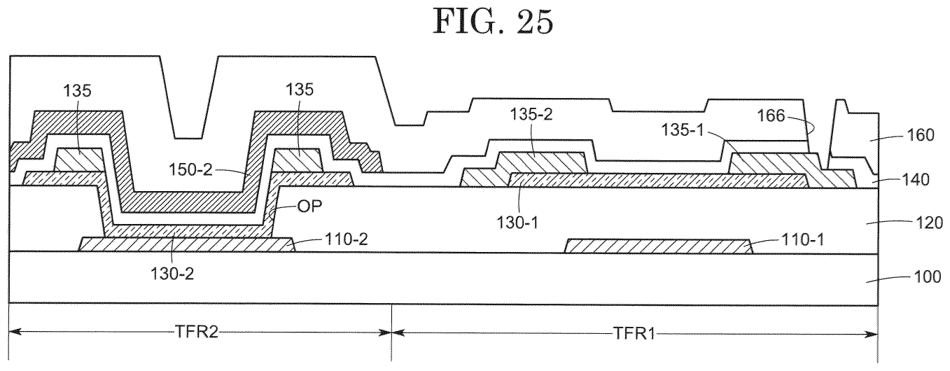

Next, as shown in FIG. 21 and FIG. 25, the third insulating layer (the insulating layer 160) is formed to cover the conductive layer 150-2 (step S1085). Since the formation of the insulating layer 160 is similar to the step S1080 shown in FIG. 6 in the first embodiment, a detailed explanation thereof will be omitted. After the insulating layer 160 is formed, a contact hole 166 is formed in a portion of the insulating layers 140 and 160 that overlaps the source region SR of the oxide semiconductor layer 130-1. The contact hole 166 is an opening for electrically connecting the pixel electrode 200, which will be described later, to the conductive layer 135-1.

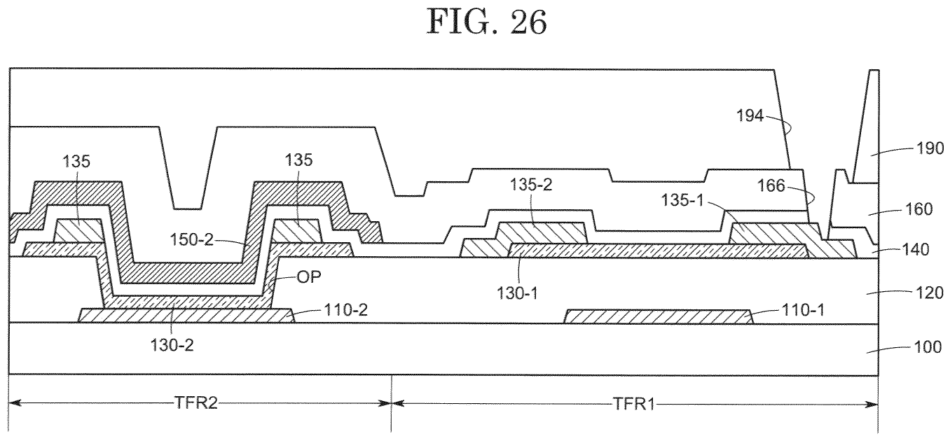

Next, as shown in FIG. 21 and FIG. 26, the fourth insulating layer (the insulating layer 190) is formed on the insulating layer 160 (step S1105). Since the formation of the insulating layer 190 is similar to the step S1100 shown in FIG. 6 in the first embodiment, a detailed explanation thereof will be omitted. In the present embodiment, a photosensitive acryl material is used to form the insulating layer 190, and a contact hole 194 is formed in a portion of the insulating layer 190 that overlaps the conductive layer 135-1.

In a plan view, the contact hole 194 provided in the insulating layer 190 includes all or a portion of the contact hole 166 provided in the insulating layer 160. Specifically, the contact hole 194 is provided to overlap the contact hole 166 so that a portion of the conductive layer 135-1 is exposed. In the present embodiment, although an example has been shown in which a diameter of the contact hole 166 is smaller than a diameter of the contact hole 194, the present invention is not limited to this, and the diameter of the contact hole 194 may be smaller than the diameter of the contact hole 166. That is, the contact hole 194 may be formed inside the contact hole 166.

Finally, the steps S1110 to S1130 are executed according to the flowchart of FIG. 6 described in the first embodiment. Through the above-described process, a semiconductor device including the transistors Tr1-1 and Tr2 in each pixel 13-1 is completed. In the present embodiment, the transistor Tr1-1, which is a bottom-gate transistor, and the transistor Tr2, which is a vertical transistor, are formed on the same substrate by the same process. That is, according to the present embodiment, similar to the first embodiment, since transistors having completely different structures can be formed by the same process, the degree of freedom in circuit design can be improved.

Each of the embodiments described above as an embodiment of the present invention can be appropriately combined and implemented as long as no contradiction is caused. Further, the addition, deletion, or design change of components, or the addition, deletion, or condition change of processes as appropriate by those skilled in the art based on each embodiment are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A semiconductor device comprising:
a first transistor including a first oxide semiconductor layer on a first insulating layer, a second insulating layer on the first oxide semiconductor layer and a first gate electrode on the second insulating layer; and
a second transistor including a second oxide semiconductor layer covering an opening arranged in the first insulating layer, the second insulating layer being located on the second oxide semiconductor layer and a second gate electrode being located on the second insulating layer, wherein
the second transistor is configured such that a portion of the second oxide semiconductor layer along a sidewall of the opening functions as a channel.

2. The semiconductor device according to claim 1 wherein
the second transistor further includes a first terminal electrode and a second terminal electrode,
the first terminal electrode contacts a bottom surface of the second oxide semiconductor layer inside the opening, and
the second terminal electrode contacts a top surface of the second oxide semiconductor layer outside the opening.

3. The semiconductor device according to claim 2 wherein
the second terminal electrode is positioned between the second oxide semiconductor layer and the second insulating layer.

4. The semiconductor device according to claim 2 wherein
the second terminal electrode is arranged to surround the opening in a plan view.

5. The semiconductor device according to claim 2 wherein
the first transistor further includes a third gate electrode beneath the first insulating layer, and
the third gate electrode and the first terminal electrode are formed in the same layer.

6. The semiconductor device according to claim 1 wherein
the first oxide semiconductor layer and the second oxide semiconductor layer are formed in the same layer.

7. The semiconductor device according to claim 1 wherein
the first gate electrode and the second gate electrode are formed in the same layer.

8. A semiconductor device comprising:
a first transistor including a first gate electrode on an insulating surface, a first insulating layer on the first gate electrode and a first oxide semiconductor layer on the first insulating layer; and
a second transistor including a second oxide semiconductor layer covering an opening arranged in the first insulating layer, a second insulating layer being located on the second oxide semiconductor layer and a second gate electrode being located on the second insulating layer, wherein
the second transistor is configured such that a portion of the second oxide semiconductor layer along a sidewall of the opening functions as a channel.

9. The semiconductor device according to claim 8 wherein
the second transistor further includes a first terminal electrode and a second terminal electrode,
the first terminal electrode contacts a bottom surface of the second oxide semiconductor layer inside the opening, and
the second terminal electrode contacts a top surface of the second oxide semiconductor layer outside the opening.

10. The semiconductor device according to claim 9 wherein
the second terminal electrode is positioned between the second oxide semiconductor layer and the second insulating layer.

11. The semiconductor device according to claim 9 wherein
the second terminal electrode is arranged to surround the opening in a plan view.

12. The semiconductor device according to claim 9 wherein
the first transistor further includes a third terminal electrode and a fourth terminal electrode on the first oxide semiconductor layer, and
the third terminal electrode and the fourth terminal electrode are formed in the same layer as the second terminal electrode.

13. The semiconductor device according to claim 12 wherein
the third terminal electrode and the fourth terminal electrode are positioned between the first oxide semiconductor layer and the second insulating layer.

14. The semiconductor device according to claim 8 wherein
the first oxide semiconductor layer and the second oxide semiconductor layer are formed in the same layer.

15. The semiconductor device according to claim 9 wherein
the first gate electrode and the second gate electrode are formed in the same layer.

16. A display device comprising the semiconductor device according to claim 1.

17. A display device comprising an organic electroluminescent element connected to the semiconductor device according to claim 1, wherein
the organic electroluminescent element is electrically connected to a source or a drain of the first transistor, and
the source or the drain of the second transistor is electrically connected to a gate of the first transistor.
